(19) United States
(12) Patent Application Publication
(10) Pub. No.: US 2025/0374499 A1
(43) Pub. Date: Dec. 4, 2025

(54) SUBSTRATE PRODUCTION MACHINE AND SUBSTRATE PRODUCTION LINE

(71) Applicant: FUJI CORPORATION, Chiryu (JP)

(72) Inventors: Akiyoshi TAKAMURA, Chiryu-shi (JP); Tomohiro YAMAZAKI, Nishio-shi (JP)

(73) Assignee: FUJI CORPORATION, Chiryu (JP)

(21) Appl. No.: 18/857,341

(22) PCT Filed: Jun. 6, 2022
(86) PCT No.: PCT/JP2022/022744

§ 371 Date: Aug. 20, 2025

(51) Int. Cl. H05K 13/08

(52) U.S. Cl. CPC H05K 13/0885

(57) ABSTRACT

A board production machine includes a first control device configured to execute first control related to production of a board, a second control device communicably connected to the first control device and configured to execute second control different from the first control, a first breaker configured to turn on/off power supply to the first control device, and a second breaker configured to turn on/off power supply to the second control device.

### TECHNICAL FIELD

The present description discloses a board production machine and a board production line.

### BACKGROUND ART

Conventionally, there has been proposed a system in which control circuits are individually linked to individual devices constituting industrial equipment (consistent production line or the like), and a breaker circuit is provided in each device (for example, refer to Patent Literature 1).

### CITATION LIST

### Patent Literature

Patent Literature 1: JP-A-6-62521

### SUMMARY OF THE INVENTION

### Technical Problem

In the system described above, although it is described that the breaker circuits are provided in the individual devices constituting the industrial equipment, there is no mention of installing a breaker in a board production machine that produces boards on which components are mounted.

A main object of the present disclosure is to enable operation of a second control device even when power supply of a first control device is turned off in a board production machine including the first control device that performs control related to board production and the second control device that performs other controls.

### Solution to Problem

The present disclosure employs the following means in order to achieve the main object described above.

According to an aspect of the present disclosure, there is provided a board production machine for producing a board on which a component is mounted, the board production machine including:
a first control device configured to execute first control related to production of the board;
a second control device communicably connected to the first control device and configured to execute second control different from the first control;
a first breaker configured to turn on/off power supply to the first control device; and
a second breaker configured to turn on/off power supply to the second control device.

In the board production machine of the present disclosure, different breakers are installed in the first control device that executes the first control related to the production of the board and the second control device that executes the second control different from the first control. Accordingly, in the board production machine, it is possible to operate the second control device even when the power supply of the first control device is turned off.

According to another aspect of the present disclosure, there is provided a board production line including multiple board production machines that are arranged, each board production machine including:
a first control device configured to execute first control related to production of a board;
a second control device communicably connected to the first control device and configured to execute second control different from the first control;
a first breaker configured to turn on/off power supply to the first control device; and
a second breaker configured to turn on/off power supply to the second control device.

The board production line of the present disclosure exerts the same effects as those of the board production machine of the present disclosure.

### BRIEF DESCRIPTION OF DRAWINGS

FIG. 1 is an external perspective view of a board production line.

FIG. 2 is an external perspective view of a component mounter.

FIG. 3 is a schematic configuration diagram of the component mounter.

FIG. 4 is a block diagram illustrating an electrical connection relationship of each module of a board production line.

FIG. 5 is a diagram illustrating the flow of each operation of a screen control application, a screen control device OS, a module device OS, and a module application when a main breaker is turned off.

FIG. 6 is a diagram illustrating the flow of each operation of the screen control application, the screen control device OS, the module device OS, and the module application when the main breaker is turned on again.

FIG. 7 is a diagram illustrating the flow of each operation of the screen control application, the screen control device OS, the module device OS, and the module application when a sub-breaker is turned off.

FIG. 8 is a diagram illustrating the flow of each operation of the screen control application, the screen control device OS, the module device OS, and the module application when the sub-breaker is turned on again.

### DESCRIPTION OF EMBODIMENTS

Next, an embodiment of the present disclosure will be described with reference to the drawings.

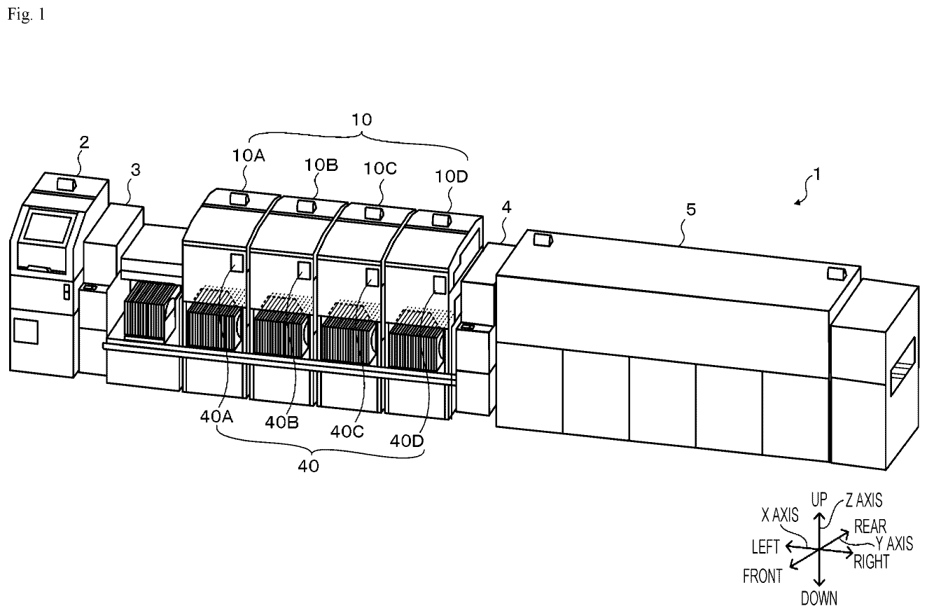

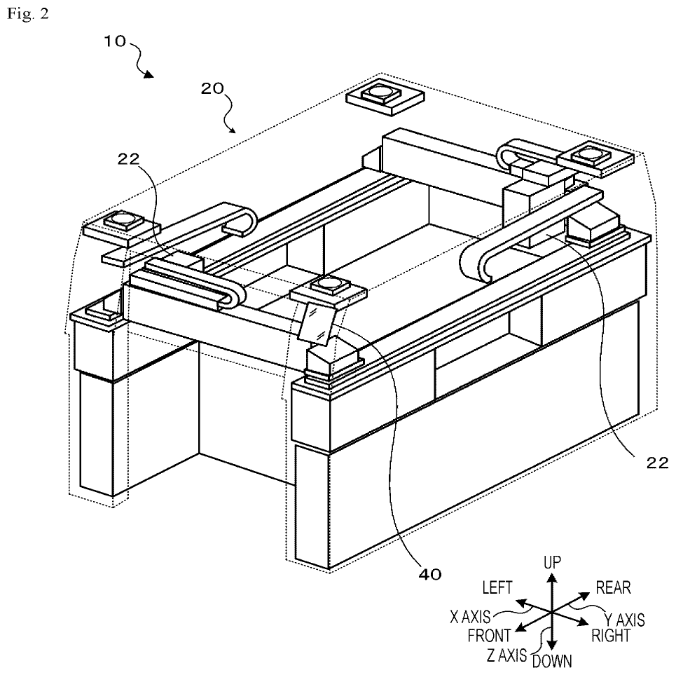

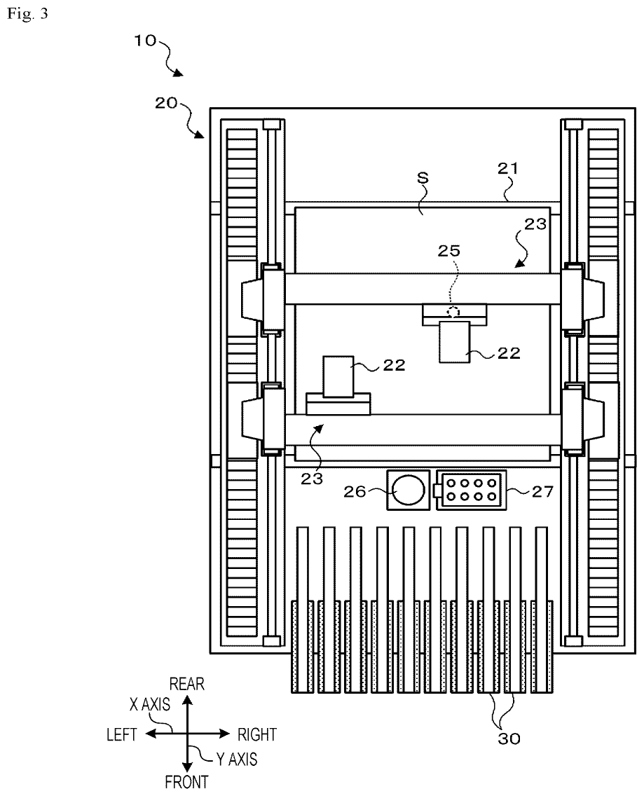

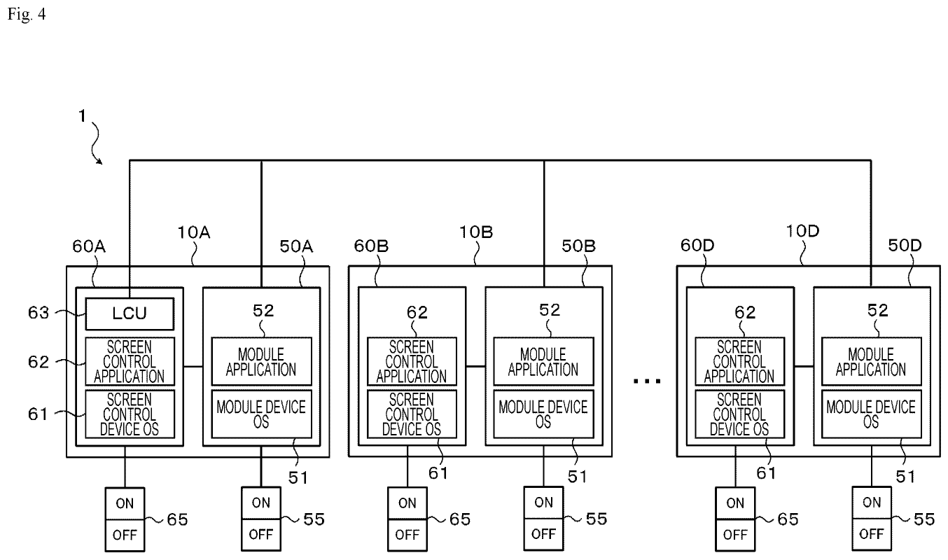

FIG. 1 is an external perspective view of board production line 1. FIG. 2 is an external perspective view of component mounter. FIG. 3 is a schematic configuration diagram of component mounter 10. FIG. 4 is a block diagram illustrating an electrical connection relationship of each component mounter 10 of board production line 1. In FIG. 1 and FIG. 2, a left-right direction represents an X-axis direction, a front-rear direction represents a Y-axis direction, and an up-down direction represents a Z-axis direction.

Board production line 1 of the present embodiment is for producing board S on which components are mounted, and a board production machine (module) constituting board production line 1 includes printing machine 2, printing inspection machine 3, multiple component mounters 10 (10A, 10B, 10C, and 10D), mounting inspection machine 4, reflow oven 5, and the like, as illustrated in FIG. 1. These are arranged along a conveyance direction of board S. Printing machine 2 prints solder on board S by pushing the solder into pattern holes formed in a screen mask. Printing inspection machine 3 inspects a state of the solder printed by printing machine 2. Mounting inspection machine 4 inspects the mounting state of the components mounted on board S by component mounter 10 (10A, 10B, 10C, and 10D). Reflow oven 5 melts the solder by heating board S on which the component is disposed on the solder and then cools the solder, and thereby, the component is electrically connected to board S to be fixed to board S.

As illustrated in FIGS. 2 and 3, each component mounter 10 (10A, 10B, 10C, and 10D) includes mounter main body 20 including board conveyance device 21, head 22, and head moving device 23, feeder 30 for supplying components to mounter main body 20, and operation panel 40 (40A, 40B, 40C, and 40D) having a touch panel type screen. Further, as illustrated in FIG. 4, each component mounter 10 includes module control device 50 (50A, 50B, . . . , 50D) for controlling mounter main body 20, and screen control device 60 (60A, 60B, . . . , and 60D) for controlling the screen of operation panel 40.

Board conveyance device 21 is a belt conveyor device that conveys board S to the left and right (X-axis direction) with a conveyor belt.

Head 22 includes a holder to which a suction nozzle (collection member) is detachably attached, and a lifting and lowering device that lifts and lowers the holder up and down (in the Z-axis direction). A negative pressure from a negative pressure source is supplied to the suction nozzle via a solenoid valve, and the suction nozzle can pick up (collect) components by the negative pressure. Head moving device 23 moves head 22 in the front-rear and left-right directions (XY axis directions). Head moving device 23 includes a Y-axis slider that moves in the front-rear direction (in the Y-axis direction) by being driven by a Y-axis motor, and an X-axis slider that moves in the left-right direction (in the X-axis direction) with respect to the Y-axis slider by being driven by an X-axis motor. Head 22 is attached to the X-axis slider, and moves in the front-rear and left-right directions (XY axis directions) by being driven by the X-axis motor and the Y-axis motor. In the present embodiment, as illustrated in FIGS. 2 and 3, component mounter 10 includes two heads 22 capable of moving independently of each other in each head moving device 23.

Moreover, component mounter 10 also includes mark camera 25, part camera 26, and nozzle stocker 27. Mark camera 25 captures an image of a reference mark attached to board S from above in order to detect the position of board S. Part camera 26 captures an image of a component picked up by the suction nozzle from below in order to detect a pickup error or a pickup deviation. Nozzle stocker 27 stocks multiple types of suction nozzles attachable to the holder of head 22.

Module control device 50 (50A, 50B, . . . , and 50D) is configured as a microprocessor centered on the CPU, and includes, in addition to the CPU, ROM, RAM, a storage, an input/output port, a communication port, and the like. Module control device 50 inputs a detection signal from a position sensor for detecting each position of head 22 in the X-axis direction and the Y-axis direction, and inputs a signal of an image captured by part camera 26 or mark camera 25. Module control device 50 outputs control signals to feeder 30, board conveyance device 21, head moving device 23, part camera 26, mark camera 25, and the like.

As illustrated in FIG. 4, module device OS 51 is installed in the storage of module control device 50, and module application (hereinafter, referred to as a module application) 52 is installed in module device OS 51. The CPU of module control device 50 controls mounter main body 20 by executing module application 52 under the management of module device OS 51. Control of mounter main body 20 mainly includes collection control and mounting control. The collection control is performed by controlling head moving device 23 so that head 22 moves above a component supply position of feeder 30, and then controlling head 22 (lifting and lowering device) so as to lower the suction nozzle of head 22 and collect the component at the component supply position. The mounting control is performed by controlling head moving device 23 so that head 22 moves above the designated mounting position of board S, and then controlling head 22 (lifting and lowering device) so that the suction nozzle of head 22 is lowered and the component is mounted at the mounting position.

Screen control device 60 (60A, 60B, . . . , and 60D) is configured as a microprocessor centered on the CPU, and includes, in addition to the CPU, ROM, RAM, a storage, an input/output port, a communication port, and the like. Screen control device 60 is communicably connected to module control device 50 via the communication port, and displays the operating state of corresponding component mounter 10 and other information on corresponding operation panel 40 (40A, 40B, 40C, and 40D) in cooperation with module control device 50.

As illustrated in FIG. 4, screen control device OS 61 is installed in the storage of screen control device 60, and screen control application (hereinafter, referred to as screen control application) 62 is installed in screen control device OS 61. The CPU of screen control device 60 controls the display of the screen by executing screen control application 62 under the management of screen control device OS 61. The display content includes, for example, status information indicating the operation status of component mounter 10, such as during the production or during the setup change, and during the occurrence of an abnormality.

A breaker (main breaker 55, sub-breaker 65) is separately provided in each of module control device 50 and screen control device 60. Main breaker 55 switches between supplying and cutting off power to module control device 50, and sub-breaker 65 switches between supplying and cutting off power to screen control device 60 independently of module control device 50. Module control device 50 includes a power storage device, and when main breaker 55 is turned off, module control device 50 can operate for a certain period of time by using electric power of the power storage device. Similarly, screen control device 60 includes a power storage device, and when sub-breaker 65 is turned off, screen control device 60 can operate for a certain period of time using the electric power of the power storage device.

Further, screen control device 60A of component mounter 10A, which is one of multiple component mounters 10 (10A, 10B, 10C, and 10D), and module control device 50 of each of the component mounters 10 (10A, 10B, 10C, and 10D) are communicably connected via a file transfer protocol (FTP). In addition to screen control application 62, a line control unit (hereinafter referred to as LCU) 63 for managing board production line 1 is installed in screen control device OS 61 of screen control device 60A as illustrated in FIG. 4. The CPU of screen control device 60A executes LCU 63 under the management of screen control device OS 61, and instructs each component mounter 10 to mount the component by communication in accordance with the production schedule stored in the storage. The production schedule specifies which components are to be mounted on which boards S in which order by each component mounter 10, and how many boards S thus mounted are to be produced. In addition to each component mounter 10, LCU 63 also manages printing machine 2, printing inspection machine 3, mounting inspection machine 4, and reflow oven 5 described above.

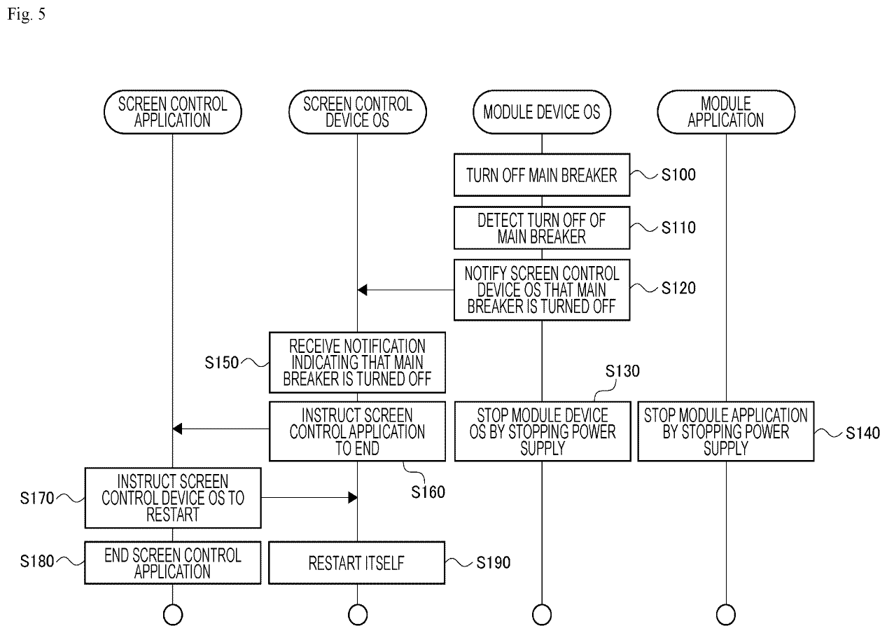

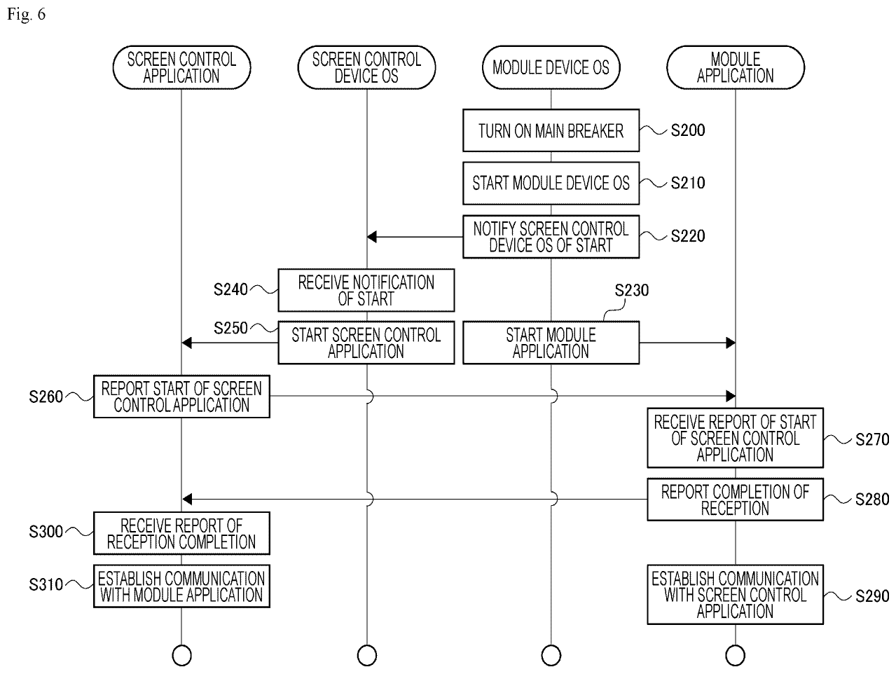

Next, an operation of board production line 1 configured as described above will be described. In particular, an operation when main breaker 55 is turned off and then turned on again, and an operation when sub-breaker 65 is turned off and then turned on again will be described. FIG. 5 is a diagram illustrating the flow of each operation of screen control application 62, screen control device OS 61, module device OS 51, and module application 52 when main breaker 55 is turned off. FIG. 6 is a diagram illustrating the flow of each operation of screen control application 62, screen control device OS 61, module device OS 51, and module application 52 when main breaker 55 is turned on again.

As illustrated in FIG. 5, when main breaker 55 is turned off by a worker (Step S100) and it is detected that main breaker 55 is turned off (Step S110), module device OS 51 notifies screen control device OS 61 that main breaker 55 is turned off (Step S120). As described above, even when main breaker 55 is turned off, since module control device 50 operates for a certain period of time from the electric power from the power storage device, during the certain period of time, module device OS 51 notifies screen control device OS 61 that main breaker 55 is turned off. Thereafter, module device OS 51 stops when the power supply is stopped by turning off main breaker 55 (Step S130). Module application 52 also stops when the power supply is stopped by turning off main breaker 55 (Step S140). Since sub-breaker 65 remains on, the power supply to screen control device 60 is maintained.

Screen control device OS 61 receives a notification indicating that main breaker 55 is turned off from module device OS 51 (Step S150), and instructs screen control application 62 to end the application (Step S160). When the end of the application is instructed, screen control application 62 instructs screen control device OS 61 to restart (Step S170), and then ends the application (Step S180). When the restart is instructed from screen control application 62, screen control device OS 61 restarts itself (Step S190).

As illustrated in FIG. 6, when main breaker 55 is turned on again by the worker (Step S200) and module device OS 51 is started by the power supply (Step S210), module device OS 51 notifies screen control device OS 61 that the start of module device OS 51 is completed (Step S220), and starts module application 52 (Step S230). Upon receiving the notification of the completion of the start of module device OS 51 (Step S240), screen control device OS 61 starts screen control application 62 (Step S250). When screen control application 62 starts, screen control application 62 reports the completion of the start of screen control application 62 to module application 52 (Step S260). Upon receiving the report of the completion of the start of screen control application 62 (Step S270), module application 52 reports the completion of reception to screen control application 62 (Step S280), and establishes communication with screen control application 62 (Step S290). Meanwhile, screen control application 62 receives the report of reception completion from module application 52 (Step S300), and establishes communication with module application 52 (Step S310). Accordingly, communication between module application 52 and screen control application 62 becomes possible, and screen control application 62 receives various information from module application 52 by communication, and displays the received various information on operation panel 40.

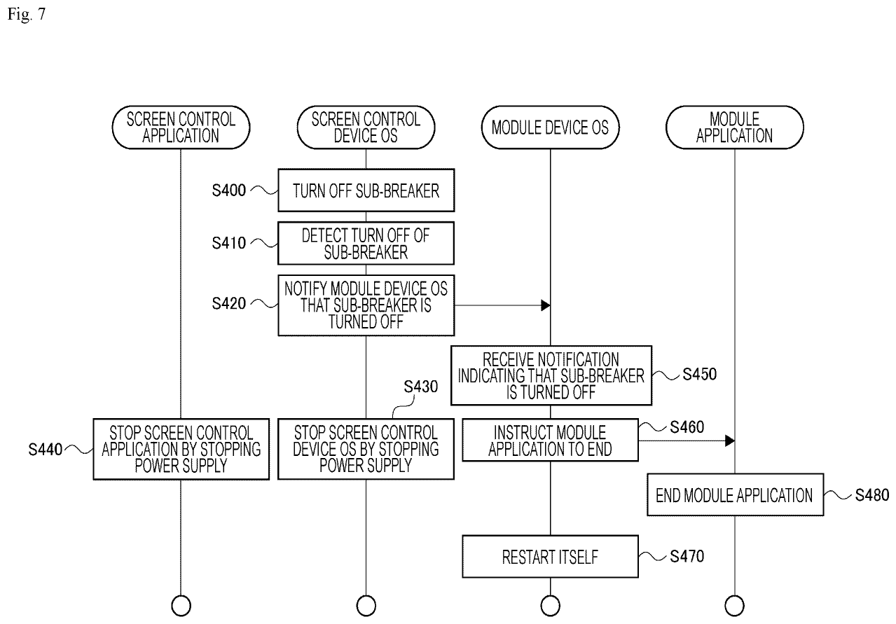

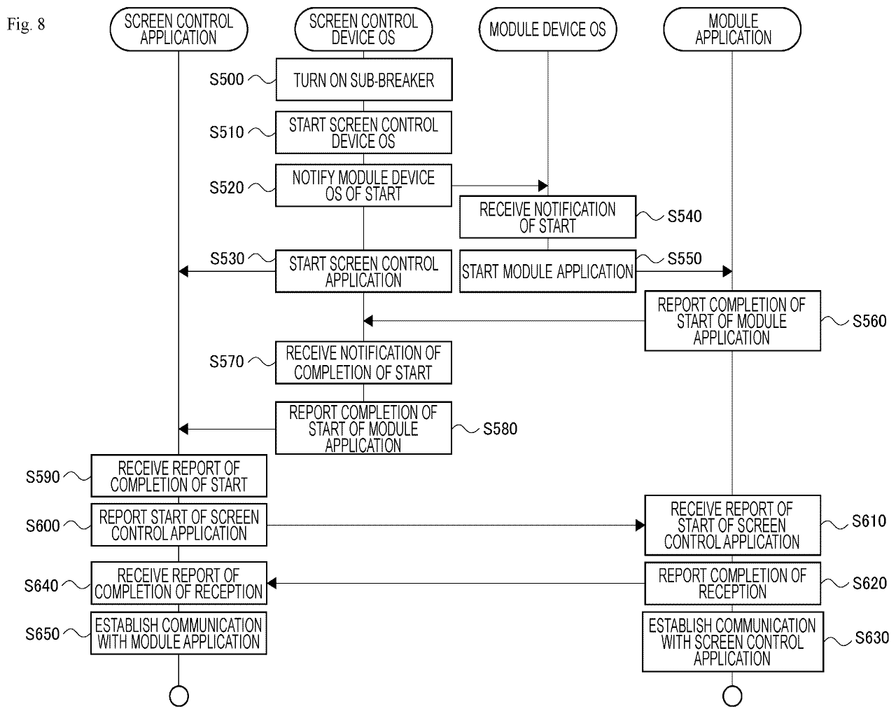

FIG. 7 is a diagram illustrating the flow of each operation of screen control application 62, screen control device OS 61, module device OS 51, and module application 52 when sub-breaker 65 is turned off. FIG. 8 is a diagram illustrating the flow of each operation of screen control application 62, screen control device OS 61, module device OS 51, and module application 52 when sub-breaker 65 is turned on again.

As illustrated in FIG. 7, when sub-breaker 65 is turned off by the worker (Step S400) and it is detected that sub-breaker 65 is turned off (Step S410), screen control device OS 61 notifies module device OS 51 that sub-breaker 65 is turned off (Step S420). As described above, even when sub-breaker 65 is turned off, since screen control device 60 is operated by the electric power from the power storage device for a certain period of time, during the certain period of time, screen control device OS 61 notifies module device OS 51 that sub-breaker 65 is turned off. Thereafter, screen control device OS 61 stops when the power supply is stopped by turning off sub-breaker 65 (Step S430). Screen control application 62 also stops when the power supply is stopped by turning off sub-breaker 65 (Step S440). Since main breaker 55 remains on, the power supply to module control device 50 is maintained.

When module device OS 51 receives a notification indicating that sub-breaker 65 is turned off from screen control device OS 61 (Step S450), module device OS 51 instructs module application 52 to end the application (Step S460) and restarts itself (Step S470). When the end of the application is instructed, module application 52 ends module application 52.

As illustrated in FIG. 8, when sub-breaker 65 is turned on again by the worker (Step S500) and screen control device OS 61 is started by the power supply (Step S510), screen control device OS 61 notifies module device OS 51 that the start of screen control device OS 61 is completed (Step S520), and starts screen control application 62 (Step S530). When module device OS 51 receives the notification of the completion of the start of screen control device OS 61 (Step S540), module device OS 51 starts module application 52 (Step S550). When module application 52 is started, module application 52 notifies screen control device OS 61 that the start of module application 52 is completed (Step S560). Upon receiving the notification of the completion of the start from module application 52 (Step S570), screen control device OS 61 reports the completion of the start of module application 52 to screen control application 62 (Step S580). Screen control application 62 receives the report of the completion of the start of module application 52 (Step S590), and reports the completion of the start of screen control application 62 to module application 52 (Step S600). Upon receiving the report of the completion of the start of screen control application 62 (Step S610), module application 52 reports the completion of reception to screen control application 62 (Step S620), and establishes communication with screen control application 62 (Step S630). Meanwhile, screen control application 62 receives the report of the completion of the reception from module application 52 (Step S640), and establishes communication with module application 52 (Step S650). Accordingly, communication between module application 52 and screen control application 62 becomes possible, and module application 52 transmits various information to screen control application 62 by communication, and causes screen control application 62 to display various information on operation panel 40.

Here, a correspondence relationship between the elements of the present embodiment and the elements of the present invention will be clarified. Component mounter 10 (10A, 10B, 10C, and 10D) of the present embodiment corresponds to a board production machine of the present disclosure, module control device 50 (50A, 50B, . . . , and 50D) corresponds to a first control device, screen control device 60 (60A, 60B, . . . , and 60D) corresponds to a second control device, main breaker 55 corresponds to a first breaker, and sub-breaker 65 corresponds to a second breaker. Module application 52 corresponds to a first control application, and screen control application 62 corresponds to a second control application.

The present invention is not limited in any way to the above embodiment, and it is needless to say that the present invention can be carried out in various aspects without departing from the technical scope of the present invention.

For example, in the above-described embodiment, component mounter 10A is provided with LCU 63 in screen control device 60, but LCU 63 may be provided in a separate control device.

In the above-described embodiment, screen control device 60 includes screen control application 62 that controls the display of operation panel 40 in cooperation with module application 52 of module control device 50. However, any application can be applied as long as it performs control in cooperation with module application 52 of module control device 50.

Further, in the above-described embodiment, the board production machine including the first control device and the second control device is applied to component mounter 10 including module control device 50 and screen control device 60. However, the present invention is not limited to this, and may be applied to any board production machine as long as it includes, for example, a first control device related to production of a board, such as printing machine 2, printing inspection machine 3, mounting inspection machine 4, and reflow oven 5, and a second control device (for example, a control device controlling an operation panel mounted on the board production machine) that performs other control.

As described above, different breakers are installed on the first control device that executes the first control related to the production of the board and the second control device that executes the second control different from the first control. Accordingly, in the board production machine, it is possible to operate the second control device even when the power supply of the first control device is turned off.

The board production machine of the present disclosure may be one of the multiple board production machines constituting the board production line, and the second control may include management control for managing the board production line. In this way, since it is not necessary to separately provide a control device for managing the board production line, the system can be further simplified. In this case, the display device for displaying various information related to the board production machine may be provided, and the second control may include display control of the display device.

In addition, in the board production machine of the present disclosure, the first control application may be installed in an operating system of the first control device, the second control application may be installed in an operating system of the second control device, the operating system of the first control device may notify the second control device that the first breaker is turned off before stopping when the first breaker is turned off, and when the first breaker is turned on and the operating system is started during the stopping, notify the second control device of the start of the operating system, and the first control application may be started to establish communication between the first control application and the second control application, and when the operating system of the second control device receives a notification from the first control device that the first breaker is turned off, the operating system may be restarted, and when the operating system receives a notification of the start from the first control device, the second control application may be started to establish communication between the second control application and the first control application. In this way, even when the first breaker is turned off and then turned on again, it is possible to smoothly establish the communication between the first control application and the second control application.

Further, in the board production machine of the present disclosure, the first control application may be installed in the operating system of the first control device, the second control application may be installed in the operating system of the second control device, the operating system of the second control device may notify the first control device that the second breaker is turned off before stopping when the second breaker is turned off, and when the second breaker is turned on and the operating system is started during the stopping, notify the first control device of the start of the operating system, and the second control application may be started to establish communication between the second control application and the first control application, and when the operating system of the first control device receives a notification from the second control device that the second breaker is turned off, the operating system may be restarted, and when the operating system receives a notification of the start from the second control device, the first control application may be started to establish communication between the first control application and the second control application. In this way, even when the second breaker is turned off and then turned on again, it is possible to smoothly establish the communication between the first control application and the second control application.

The present disclosure is not limited to the form of the board production machine, and may be a form of a board production line.

The present description also discloses a technical idea in which the “board production machine according to claim 2” recited in claim 3 as originally filed is changed to “the board production machine according to claim 1 or 2”, and a technical idea in which the “board production machine according to any one of claims 1 to 3” recited in claim 5 as originally filed is changed to the “board production machine according to any one of claims 1 to 4”.

### INDUSTRIAL APPLICABILITY

The present disclosure can be used in a board production machine, a manufacturing industry of a board production line, and the like.

### REFERENCE SIGNS LIST

1: board production line, 2: printing machine, 3: printing inspection machine, 4: mounting inspection machine, 5: reflow oven, 10, 10A, 10B, 10C, 10D: component mounter, 20: mounter main body, 21: board conveyance device, 22: head, 23: head moving device, 25: mark camera, 26: part camera, 27: nozzle stocker, 30: feeders, 40, 40A, 40B, 40C, and 40D: operation panel, 50, 50A, 50B, . . . , and 50D: module control device, 51: module device OS, 52: module application, 55: main breaker, 60: screen control device, 60, 60A, 60B, . . . , and 60D: screen control device, 61: screen control device OS, 62: screen control application, 63: LCU, 65: sub-breaker, S: board.

1. A board production machine for producing a board on which a component is mounted, the board production machine comprising:
a first control device configured to execute first control related to production of the board;
a second control device communicably connected to the first control device and configured to execute second control different from the first control;
a first breaker configured to turn on/off power supply to the first control device; and
a second breaker configured to turn on/off power supply to the second control device.

2. The board production machine according to claim 1,
wherein the board production machine is one of multiple board production machines constituting a board production line, and
the second control includes management control for managing the board production line.

3. The board production machine according to claim 2, further comprising a display device configured to display various information related to the board production machine,
wherein the second control includes display control of the display device.

4. The board production machine according to claim 1,
wherein a first control application is installed in an operating system of the first control device,
a second control application is installed in an operating system of the second control device,
the operating system of the first control device notifies the second control device that the first breaker is turned off before stopping when the first breaker is turned off, and when the first breaker is turned on and the operating system is started during the stopping, notifies the second control device of the start of the operating system, and the first control application is started to establish communication between the first control application and the second control application, and
when the operating system of the second control device receives a notification from the first control device that the first breaker is turned off, the operating system is restarted, and when the operating system receives a notification of the start from the first control device, the second control application is started to establish communication between the second control application and the first control application.

5. The board production machine according to claim 1,
wherein a first control application is installed in an operating system of the first control device,
a second control application is installed in an operating system of the second control device,
the operating system of the second control device notifies the first control device that the second breaker is turned off before stopping when the second breaker is turned off, and when the second breaker is turned on and the operating system is started during the stopping, notifies the first control device of the start of the operating system, and the second control application is started to establish communication between the second control application and the first control application, and
when the operating system of the first control device receives a notification from the second control device that the second breaker is turned off, the operating system is restarted, and when the operating system receives a notification of the start from the second control device, the first control application is started to establish communication between the first control application and the second control application.

6. A board production line comprising:
multiple board production machines that are arranged, each board production machine including
a first control device configured to execute first control related to production of a board,
a second control device communicably connected to the first control device and configured to execute second control different from the first control,
a first breaker configured to turn on/off power supply to the first control device, and
a second breaker configured to turn on/off power supply to the second control device.
